(19) United States
(12) Patent Application Publication
(10) Pub. No.: US 2024/0349477 A1
(43) Pub. Date: Oct. 17, 2024

(54) RANDOM ACCESS MEMORY AND METHOD OF FABRICATING THE SAME

(71) Applicant: SEOUL NATIONAL UNIVERSITY R&DB FOUNDATION, Seoul (KR)

(72) Inventors: Jae-Joon KIM, Seoul (KR); Munhyeon KIM, Seoul (KR)

(73) Assignee: SEOUL NATIONAL UNIVERSITY R&DB FOUNDATION, Seoul (KR)

(21) Appl. No.: 18/635,211

(22) Filed: Apr. 15, 2024

(30) Foreign Application Priority Data
Apr. 14, 2023 (KR) 10-2023-0049265

(51) Int. Cl. H10B 12/00

(52) U.S. Cl. CPC H10B 12/00

(57) ABSTRACT

A random access memory includes a first transistor including a first gate extending in a first direction, a second transistor including a second gate extending in a second direction perpendicular to the first direction and formed on an upper portion of the first transistor, and a storage node configured to connect a first gate of the first transistor to a drain of the second transistor and storing data.

### FIELD OF THE INVENTION

The present disclosure relates to random access memory and a method of fabricating the random access memory.

### BACKGROUND

Conventional semiconductor memory devices are divided into static random access memory (SRAM) which is used as cache memory and dynamic random access memory (DRAM) which is used as a main memory. SRAM is used for a high-speed operation, but one memory cell generally includes at least six transistors and has low integration, and accordingly, there is a problem in that an area increases when implementing a high-capacity memory. In general, DRAM has a 1T1C cell structure in which one memory cell includes one transistor and one capacitor, and may be implemented in high-capacity and high integration but has a slower operation speed and shorter retention time than SRAM, and accordingly, there is a problem in that DRAM requires refresh at regular intervals even during operations other than read/write operations.

The present disclosure proposes a random access memory having a new structure that may replace SRAM and DRAM. That is, the present disclosure proposes a random access memory that may achieve high integration with a smaller number of elements compared to SRAM and increase data retention time compared to DRAM.

### PATENT PRIOR ART

An example of the related art includes Korean Patent Publication No. 10-2021-0096678 (Title of Invention: MEMORY DEVICE HAVING SHARED READ/WRITE DATA LINE FOR 2-TRANSISTOR VERTICAL MEMORY CELL)

### CONTENTS OF THE DISCLOSURE

### The Problem Trying to Solve

The present disclosure provides a random access memory having a new structure in which two transistors are vertically stacked and a method of manufacturing the random access memory.

Technical problems to be solved by the present embodiments are not limited to the technical problem described above, and other technical problems may exist.

### Means of Solving the Problem

According to an aspect of the present disclosure, a random access memory includes a first transistor including a first gate extending in a first direction, a second transistor including a second gate extending in a second direction perpendicular to the first direction and formed on an upper portion of the first transistor, and a storage node configured to connect a first gate of the first transistor to a drain of the second transistor and storing data.

According to another aspect of the present disclosure, a method of fabricating a random access memory includes forming a first transistor including a first gate extending in a first direction, forming an interlayer separation layer on an upper portion of the first transistor, and forming a second transistor, which includes a second gate extending in a second direction perpendicular to the first direction, on an upper portion of the interlayer separation layer, wherein throughout the forming of the first transistor and the forming of the second transistor includes forming a storage node connecting the first gate of the first transistor to a drain of the second transistor.

### Effects of the Invention

According to the configuration of the present disclosure, stacked two transistors are orthogonal to each other, and thus, lengths of gates of the two transistors may be designed to be different from each other. Also, a read transistor and a write transistor are arranged in different layers from each other, and thus, the degree of freedom may be obtained in memory data arrangement. Also, compared to DRAM having a conventional structure, DRAM of the present closure operate in a fast speed, and performs an energy-efficient and high-speed operation as the retention time is increased.

### BRIEF DESCRIPTION OF THE DRAWINGS

FIG. 1 is diagrams illustrating a random access memory according to an embodiment;

FIG. 2 illustrates a three-dimensional structure of a unit cell of a random access memory according to an embodiment;

FIG. 3 illustrates a cross-sectional structure of each transistor of a random access memory according to an embodiment;

FIG. 4 illustrates a random access memory having an array structure, according to an embodiment;

FIG. 5 illustrates main cross-sections of a random access memory according to an embodiment;

FIG. 6 is a flowchart illustrating a method of fabricating a random access memory according to an embodiment;

FIGS. 7 and 8 are views illustrating a method of fabricating a random access memory according to an embodiment; and

FIG. 9 is a view illustrating a random access memory according to another embodiment.

### DETAILED DESCRIPTION OF THE EMBODIMENTS

Hereinafter, embodiments of the present disclosure will be described in detail such that those skilled in the art to which the present disclosure belongs may easily implement the present disclosure with reference to the accompanying drawings. However, the present disclosure may be implemented in many different forms and is not limited to the embodiments to be described herein. In addition, in order to clearly describe the present disclosure with reference to the drawings, portions irrelevant to the description are omitted, and similar reference numerals are attached to similar portions throughout the specification.

When it is described that a portion is “connected” to another portion throughout the specification, this includes not only a case where the portion is “directly connected” to another portion but also a case where the portion is “indirectly connected” to another portion with another component therebetween. In addition, when it is described that a portion “includes” a certain component, this means that the portion may further include another component without excluding another component unless otherwise stated.

Throughout the specification of the present application, when a member is described to be located on another member, this includes not only ae case where a member is in contact with another member, but also a case where another member exists between the two members.

Hereinafter, preferred embodiments of the present disclosure will be described in detail with reference to the accompanying drawings and the following description. However, the present disclosure is not limited to the embodiments described herein and may be embodied in other forms. Like reference numerals refer to like elements throughout the specification.

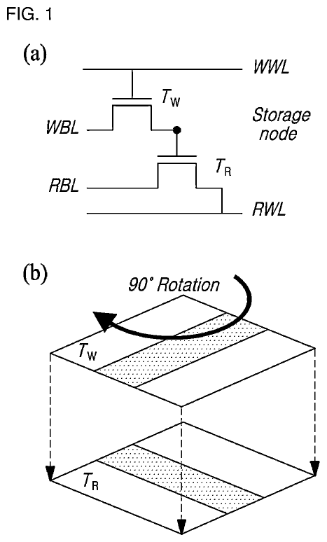

FIG. 1 is diagrams illustrating a random access memory according to an embodiment.

As illustrated in FIG. 1, a random access memory 10 of the present disclosure includes a first transistor 100 and a second transistor 200. In this case, the first transistor 100 includes a first gate 110 extending in a first direction. Also, the second transistor 200 includes a second gate 210 extending in a second direction perpendicular to the first direction and is stacked on an upper portion of the first transistor 100. Also, the random access memory 10 includes a data storage node 150 connecting the first gate 110 of the first transistor 100 to a drain of the second transistor 200. Also, the first transistor 100 operates as a read transistor for reading a state of the storage node 150, and the second transistor 200 operates as a write transistor for writing data to the storage node 150.

As such, the random access memory 10 of the present disclosure includes a 2T0C structure in which the random access memory 10 includes two transistors and does not include a separate capacitor. In addition, the first transistor 100 and the second transistor 200 may each be a field effect transistor (FET) including a gate, a drain, and a source.

It may also be considered to provide a memory cell including the first transistor 100 and the second transistor 200 arranged on the same plane and connected to each other, but in this case, there is a problem that the degree of integration is reduced because an area of two transistors has to be used. Also, even when considering stacking two transistors, a gate of the first transistor needs to be connected to a drain of the second transistor, and accordingly, additional area is essentially allocated. However, as in the present disclosure, when the first transistor 100 and the second transistor 200 are arranged orthogonally, a 2T0C memory cell structure may be implemented while using an area of one transistor. As such, the memory cell of the present disclosure may be named orthogonally stacked transistor for random access memory (OST-RAM).

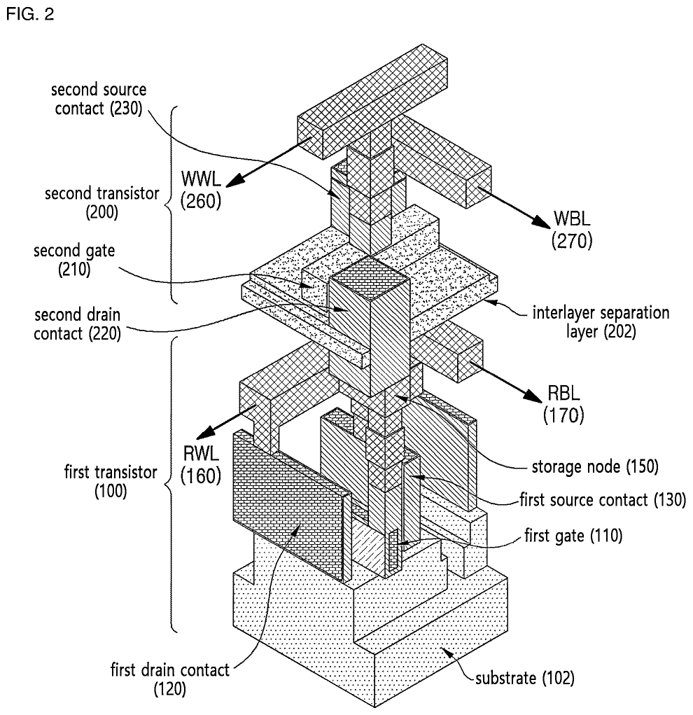

FIGS. 2 to 5 illustrate a detailed configuration of a random access memory according to an embodiment.

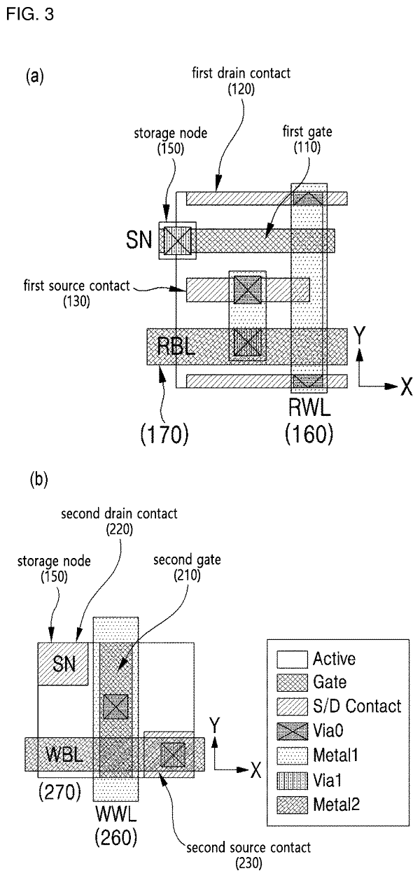

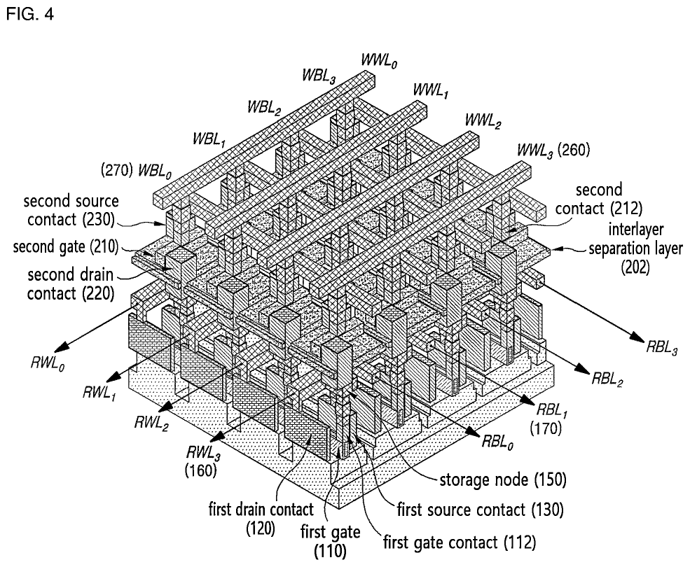

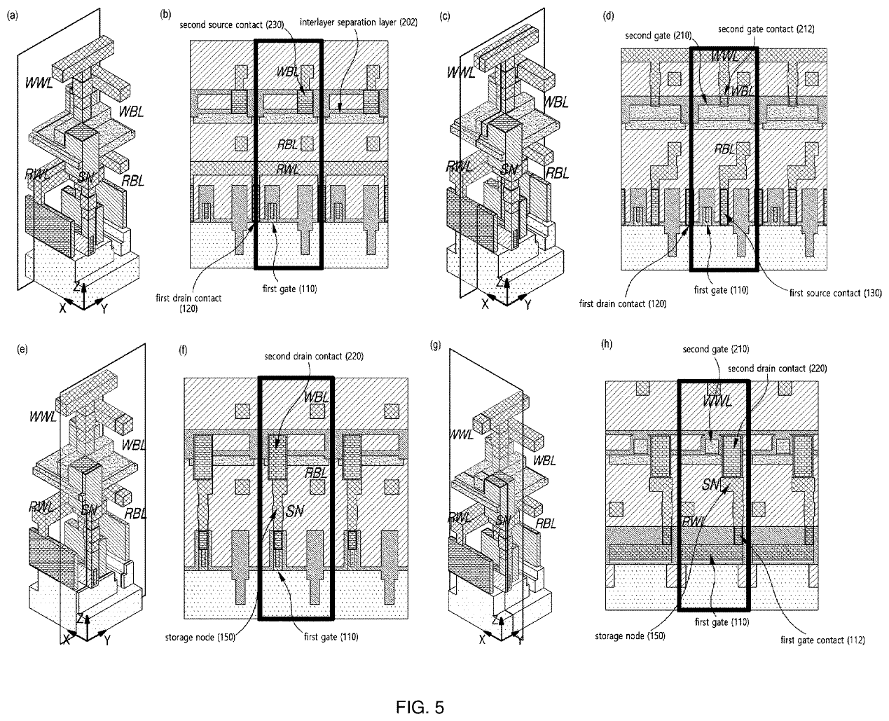

FIG. 2 illustrates a three-dimensional structure of a unit cell of a random access memory according to an embodiment, and FIG. 3 illustrates a cross-sectional structure of each transistor of a random access memory according to an embodiment. FIG. 4 illustrates a random access memory having an array structure, according to an embodiment, and FIG. 5 illustrates main cross-sections of a random access memory according to an embodiment.

As illustrated in FIGS. 2 to 5, the first transistor 100 includes the first gate 110 extending in a first direction (for example, the X-axis direction) on a substrate 102, a first drain and a first drain contact 120 formed on one side in parallel to the first gate 110, and a first source and a first source contact 130 formed on the other side of the first gate 110 in parallel to the first gate 110. Also, a first gate contact 112 is connected to an upper portion of the first gate 110 and is connected to the storage node 150. The storage node 150 connects the first gate contact 112 to a drain of the second transistor 200 in a straight line. Also, the first drain contact 120 is connected to a read word line RWL or 160 extending in the second direction (for example, the Y-axis direction), and the first source contact 130 is connected to a read bit line RBL or 170 extending in the first direction.

The second transistor 200 includes an interlayer separation layer 202 stacked on an upper portion of the first transistor 100, a second gate 210 formed on the interlayer separation layer 202 in an extending shape in the second direction, a second drain and a second drain contact 220 formed on one side of the second gate 210, and a second source and a second source contact 230 formed on the other side of the second gate 210. Also, a second gate contact 212 is connected to an upper portion of the second gate 210. Also, the second gate contact 212 of the second gate 210 is connected to a write word line WWL or 260 extending in the second direction, and the second source contact 230 is connected to a write bit line WBL or 270 extending in the first direction.

In this case, the first drain contact 120 and the first source contact 130 are formed to have different heights such that the read word line RWL or 160 and the read bit line RBL or 170 and are placed at different heights from each other while intersecting each other and are not overlapped with each other. Likewise, the second gate contact 212 and the second source contact 230 are formed to have different heights from each other such that the write word line WWL or 260 and the write bit line WBL or 270 are placed at different heights from each other while intersecting each other and are not overlapped with each other.

A main cross-section is described with reference to FIG. 5. FIG. 5B illustrates a cross-section perpendicular to the X axis as illustrated in FIG. 5B, and particularly, FIG. 5B illustrates a cross-section of the read word line RWL divided along the Y axis. FIG. 5D illustrates a cross-section perpendicular to the X axis as illustrated in FIG. 5C, and particularly, FIG. 5D illustrates a cross-section of the write word line WWL divided along the Y axis. FIG. 5F illustrates a cross-section perpendicular to the X axis as illustrated in FIG. 5E, and particularly, FIG. 5F illustrates a cross-section of a storage node divided along the Y axis. FIG. 5H illustrates a cross-section perpendicular to the Y axis as illustrated in FIG. 5G, and particularly, FIG. 5H illustrates a cross-section of the storage node divided along the X axis.

As illustrated in FIG. 5B, it can be seen that the read word line RWL is connected to the drain contact 120 of the first transistor 100 of each cell, and the source contact 230 of the second transistor 200 is connected to the write bit line WBL.

Also, as illustrated in FIG. 5D, it can be seen that the gate 210 of the second transistor 200 of each cell is connected to the write word line WWL and the source contact 130 of the first transistor 100 is connected to the read bit line RBL. In this case, it can be seen that the read bit line RBL is bent by applying a wide metal between vias, which is to obtain a sufficient process margin with the storage node 150. However, this corresponds to an optional design matter, and it is possible to perform straight wiring rather than shifted wiring by improving an etch angle of the storage node 150.

Also, as illustrated in FIG. 5F, it can be seen that the storage node 150 is connected in a straight line to the gate 110 of the first transistor 100 and a drain of the second transistor 200.

Likewise, as illustrated in FIG. 5H, it can be seen that the storage node 150 is connected in a straight line to the gate 110 of the first transistor 100 and the drain of the second transistor 200. In this case, it can be seen that a contact hole is formed relatively wide to provide a process margin for the second transistor 200 and the gate 210 and the drain contact 220 are designed to be as close as possible to increase capacitance of the storage node 150.

Meanwhile, the first transistor 100 may be formed based on single crystal silicon for high-speed read operation. Also, the first transistor 100 may be formed based on a material with high mobility, such as carbon nanotubes, a group III, or a group V. In addition, the second gate 210 of the second transistor 200 has to be deposited on an upper portion of the interlayer separation layer 202, thereby being formed of polysilicon, low-temperature polysilicon (LTPS), or an indium gallium zinc oxide (IGZO) material which is used in fabricating a flash memory. Particularly, when using a material with a high bandgap such as IGZO, an off-current may be reduced by 10 time to 100 times compared to the low-temperature polysilicon, which is advantageous in increasing retention time.

In addition, the first transistor 100 may be implemented in one of various forms, such as a planar device in the illustrated embodiment, a FinFET, a gate all around (GAA)-FET, a nanosheet (NS)-FET, a nanowire (NW)-FET, or a negative capacitance (NC)-FET. Also, the second transistor 200 may further reduce the off-current by using a device structure, such as a tunnel FET (TFET), a recess channel array transistor (RCAT), or a saddle fin transistor.

Also, a length of the first gate 110 of the first transistor 100 and a length of the second gate 210 of the second transistor 200 may be set independently of each other. That is, the length of the first gate 110 and the length of the second gate 210 may be set to be equal or different from each other. In particular, the first transistor 100 used as a read transistor is designed to include the first gate 110 having a short length for a high-speed operation, and the second transistor 200 used as a write transistor is designed to include the second gate 210 having a long length for improving retention characteristics. When an orthogonal structure is not adopted, gate lengths of the first transistor 100 and the second transistor 200 have to be designed to be equal to each other, but as in the present disclosure, gate lengths of respective transistors may be designed to be different from each other by using a structure in which two transistors that are stacked perpendicularly are orthogonal to each other.

Also, because the read transistor and the write transistor are placed in different layers, a degree of freedom is obtained in a memory data arrangement. Because word lines and bit lines are formed in each transistor, in a case where transposition is required for data when fabricating a memory array, when a direction of a cell transistor is fixed and only the routing of the write word line WWL of a write transistor and the read word line RWL of a read transistor is transposed to be designed, data transposition may be made efficiently.

According to the structure of the present disclosure, an effect may also be improved in terms of cell operation. Compared to DRAM having a conventional structure, DRAM of the present disclosure increase in operation speed and increases in retention time, and thereby, an energy-efficient and high-speed operation may be expected. In particular, the retention time may be calculated by dividing capacitance of a storage node by an off-current. Therefore, retention time may be increased by increasing capacitance of a storage node or reducing an off-current.

In order to increase the capacitance of the storage node, capacitance of a drain of the second transistor 200 needs to be increased, and accordingly, the semiconductor memory device may be designed such that a distance between the gate 210 and the drain contact 220 is reduced, a material is optimized to increase a dielectric constant of a thin film, or an area between the gate 210 and the drain contact 220 is increased.

In addition, in order to reduce the off-current, for the second transistor 200, low-temperature polysilicon (LTPS) or an IGZO material may be used as a channel material, an asymmetric junction may be formed by reducing overlap between a source and a gate, or an element structure, such as a tunnel FET (TFET), a recess channel array transistor (RCAT), or a saddle fin, may be adopted.

Hereinafter, a method of fabricating random access memory is described.

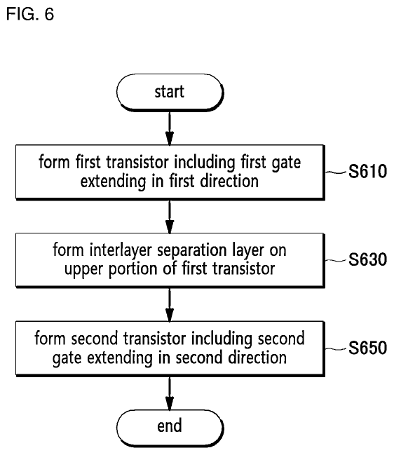

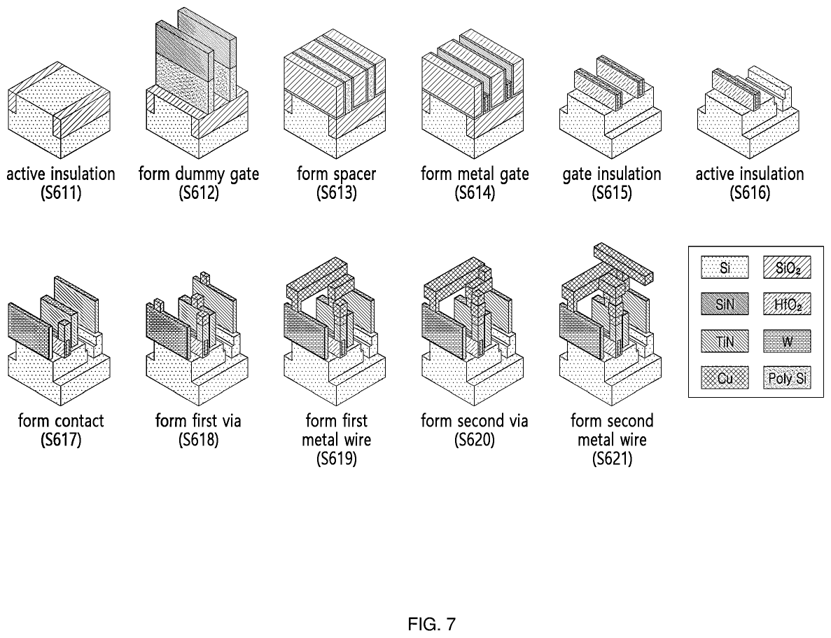

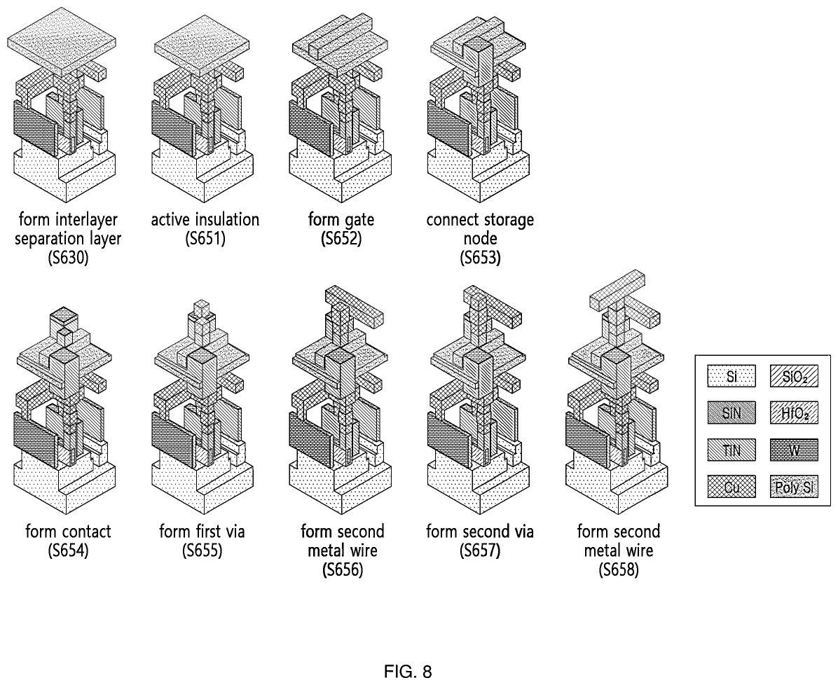

FIG. 6 is a flowchart illustrating a method of fabricating a random access memory according to an embodiment, and FIGS. 7 and 8 are views illustrating a method of fabricating a random access memory according to an embodiment.

First, the first transistor 100 including the first gate 110 extending in the first direction is formed (S610).

Referring to FIG. 7, a detailed process includes forming an active region for forming a transistor on a substrate, and dividing the active region for each unit cell (S611), forming dummy gates on the active region (S612), forming a spacer between the dummy gates, and performing a planarization process (S613), and removing the dummy gates, forming a metal gate in a space from which the dummy gates are removed, and removing the spacer (S614). In this case, atomic layer deposition may be used to form the spacer, and a material, such as SiON, SiOCN, or SiOC may be used for the spacer. Also, a metal gate process may form SiO₂ and deposit high dielectric materials, such as HfO₂, through an interlayer (IL) process. Additionally, materials, such as Al₂O₃ or La₂O₃ may be stacked in a stacked structure for work function engineering. Also, TiN, Al, TiAlC, TiAl, W, and so on may be used as materials for the metal gate. In addition, the metal gate may extend in the first direction.

Next, the gate is insulated (S615), a gate region is opened and etched, and after etching, an insulating material is deposited, and in this case, SiN may generally be used as the insulating material. Thereafter, a single diffusion break (SDB) process may be applied to electrically insulate a source and a drain of a single cell. For details of the SDB process, it is assumed that driving strength is 1 (1×), and when the driving strength is 2× or 4×, a single cell has 2 or 4 gates instead of 1, and a process of etching adjacent gates and filling with an insulator may be performed.

Thereafter, contacts connected to upper portions of the gate and source are formed (S617), vias are formed (S618), wires for the read word line are formed (S619), vias are formed (S620), and read bit lines are formed (S619). In this case, various contact techniques, such as self-aligned contact and direct patterned contact may be applied. In addition, a backend-of-line (BEOL) process for a transistor is performed in the order of a first via, a first metal wire, a second via, and a second metal wire, and metal wires are orthogonal to form two layers. In this case, both a single damascene process and a dual damascene process may be applied. The metal material is generally Cu, and an electro plate process is used therefor, and Ru, Ti, and TiN may be applied to Cu liner.

In this case, in the process of forming metal wires and vias (S618 to S621), a metal layer is formed on an upper portion of the gate contact 112 such that the storage node 150 is formed together. As illustrated in the drawings, it can be seen that a height of the storage node 150 is equal to a height of the read bit line. In addition, the storage node 150 is formed of a metal wire, and Ti, TIN, Ni, Mo, Ru, Cu, W, or so on may be used for the metal wire.

Next, the interlayer separation layer 202 is formed on an upper portion of the first transistor 100 (S630).

The interlayer separation layer 202 divides vertical regions of the first transistor 100 and the second transistor 200 and is used as a substrate for forming the second transistor 200. In this case, the interlayer separation layer 202 functions as a channel material of the second transistor 200 and may be formed of IGZO, LTPS, or so on.

Next, the second transistor 200 including the second gate 210 extending in the second direction is formed on an upper portion of the interlayer separation layer 202 (S650). In this case, the forming (S60) of the second transistor 200 includes forming the second gate 210 extending in the second direction on an upper portion of the interlayer separation layer 202.

In addition, through the processes (S610 and 650), the storage node 150 is formed that connects the first gate 110 of the first transistor 100 to a drain of the second transistor 200.

Referring to FIG. 8, a detailed process includes insulating an active region for forming the second transistor 200 in an interlayer separation layer (S651), and forming a gate on the active region and forming gate passivation (S652). In addition, a drain is formed, and the drain is connected to the storage node 150 (S653). In the process of forming the first transistor 100, a part of the storage node 150 is formed, and the storage node 150 is completed through an additional process. In the previous processes S618 to S621, the storage node 150 is formed to the same height as the second metal wire, and a process of connecting the second metal wire to the drain of the second transistor 200 is performed. To this end, a process of etching the interlayer separation layer and depositing a contact material is performed in a form corresponding to an area of the storage node 150, and Ti, TiN, W, Ru, or so on may be used for the contact material.

Next, contacts connected to the drain, the gate, and the source are respectively formed (S654), vias are formed (S655), wires for write bit lines are formed (S656), vias are formed (S657), and wires for write word lines are formed (S658).

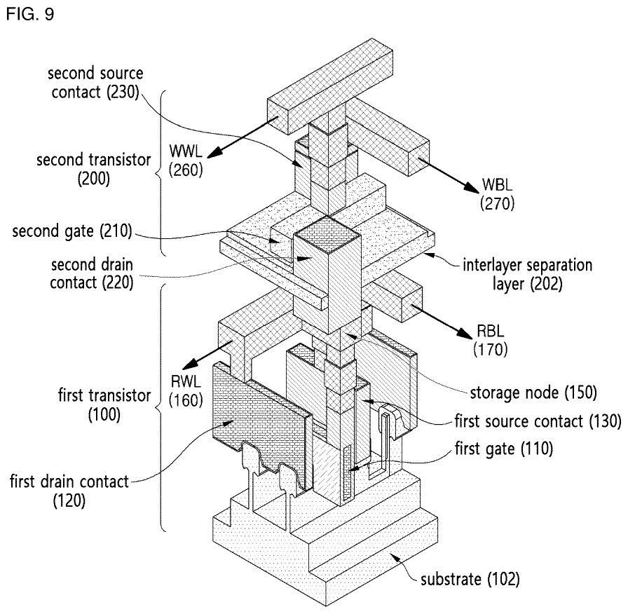

FIG. 9 illustrates a detailed configuration of a random access memory according to another embodiment.

As described above, FIG. 9 illustrates that a first transistor 100 is formed as a FinFET, and the other configurations are the same as the configurations illustrated in FIGS. 2 to 5H. That is, the first transistor 100 and a second transistor 200 are stacked in an orthogonal state, and a storage node 150 connects a first gate 110 of the first transistor 100 to a drain of the second transistor 200.

The present disclosure is characterized by a memory cell structure in which transistors are stacked in an orthogonal direction by combining CMOS technology with memory semiconductor technology. The present disclosure may be applied to a content addressable memory (CAM) field and a computing-in-memory (CiM) field in addition to memory cells.

The above descriptions of the present disclosure are for illustrative purposes only, and those skilled in the art to which the present disclosure belongs will understand that the present disclosure may be easily modified into another specific form without changing the technical idea or essential features of the present disclosure. Therefore, the embodiments described above should be understood as illustrative in all respects and not limiting. For example, each component described as a single type may be implemented in a distributed manner, and similarly, components described in a distributed manner may also be implemented in a combined form.

The scope of the present disclosure is indicated by the following claims rather than the detailed description above, and the meaning and scope of the claims and all changes or modifications derived from the equivalent concepts should be interpreted as being included in the scope of the present disclosure.

### BRIEF DESCRIPTION OF THE SIGNS

10: random access memory
100: first transistor
110: first gate
110: first gate
120: first drain contact
130: first source contact
150: storage node
160: read word line
170: read bit line
200: second transistor
210: second gate
220: second drain contact
230: second source contact
260: write word line
270: write bit line

What is claimed is:

1. A random access memory comprising:
a first transistor including a first gate extending in a first direction;
a second transistor including a second gate extending in a second direction perpendicular to the first direction and formed on an upper portion of the first transistor; and
a storage node configured to connect a first gate of the first transistor to a drain of the second transistor and storing data.

2. The random access memory of claim 1, wherein
the first transistor operates as a read transistor configured to read a state of the storage node, and
the second transistor operates as a write transistor configured to write data to the storage node.

3. The random access memory of claim 1, wherein
the first gate is formed of single crystal silicon, and
the second gate is formed of one of polysilicon, low-temperature polysilicon, and an indium gallium zinc oxide (IGZO) material.

4. The random access memory of claim 1, wherein
the first transistor includes a first drain contact formed on one side of the first gate to be parallel to the first gate, a first source contact formed on the other side of the first gate to be parallel to the first gate, a gate contact formed on an upper portion of the first gate, and a storage node connecting the gate contact to the drain of the second transistor in a straight line,
the first drain contact is connected to a read word line extending in the second direction, and
the first source contact is connected to a read bit line extending in the first direction.

5. The random access memory of claim 4, wherein
the second transistor includes, an interlayer separation layer stacked on the upper portion of the first transistor, a second gate formed on the interlayer separation layer, a second drain contact formed on one side of the second gate, and a second source contact formed on the other side of the second gate,
a contact of the second gate is connected to a write word line extending in the second direction, and
the second source contact is connected to a write bit line extending in the first direction.

6. The random access memory of claim 5, wherein
a height of the first drain contact is different from a height of the first source contact such that the read word line does not overlap the read bit line, and
a height of the second gate contact is different from a height of the second source contact such that the write word line does not overlap the write bit line.

7. The random access memory of claim 1, wherein
a length of the first gate is set independently of a length of the second gate.

8. The random access memory of claim 1, wherein
the first transistor is formed as one of a planar field effect transistor (FET), a FinFET, a gate all around (GAA)-FET, a nanosheet (NS)-FET, a nanowire (NW)-FET, or a negative capacitance (NC)-FET, and
the second transistor is formed as one of a tunnel FET (TFET), a recess channel array transistor (RCAT), or a saddle fin transistor.

9. A method of fabricating a random access memory, the method comprising:
forming a first transistor including a first gate extending in a first direction;
forming an interlayer separation layer on an upper portion of the first transistor; and
forming a second transistor, which includes a second gate extending in a second direction perpendicular to the first direction, on an upper portion of the interlayer separation layer,
wherein throughout the forming of the first transistor and the forming of the second transistor includes forming a storage node connecting the first gate of the first transistor to a drain of the second transistor.

10. The method of claim 9, wherein the forming of the first transistor includes
forming a first drain contact on one side of the first gate to be parallel to the first gate, a first source contact on the other side of the first gate to be parallel to the first gate, and a gate contact on an upper portion of the first gate, and
forming a read word line connected to the first drain contact, a read bit line connected to the first source contact, and the storage node connected to an upper portion of the gate contact, and
the storage node is sequentially stacked on the upper portion of the gate contact during the forming of the read word line and the read bit line.

11. The method of claim 10, wherein the forming of the second transistor includes
forming a second drain on one side of the second gate, a second source contact on the other side of the second gate, and a second gate contact on an upper side of the second gate, and
the second drain is connected to the storage node during the forming of the second drain.

12. The method of claim 11, wherein the forming of the second transistor further includes
forming a write word line connected to the second gate contact and a write bit line connected to the second source contact.
